(19) United States
(12) Patent Application Publication
(10) Pub. No.: US 2015/0325720 A1
(43) Pub. Date: Nov. 12, 2015

(54) Multijunction Solar Cells Lattice Matched to InP Using Sb-Containing Alloys

(71) Applicants: Robert J. Walters, Alexandria, VA (US); Phillip Jenkins, Washington, DC (US); Maria Gonzalez, Washington, DC (US); Igor Vurgaftman, Severna Park, MD (US); Jerry R. Meyer, Catonsville, MD (US); Joshua Abell, University Park, MD (US); Nicholas Ekins-Daukes, Newbury (GB); Jessica Adams, Chicago, IL (US); Paul Stavrinou, London (GB); Michael K. Yakes, Alexandria, VA (US); Joseph G. Tischler, Alexandria, VA (US); Cory D. Cress, Alexandria, VA (US); Matthew P. Lumb, Alexandria, VA (US); Ngai Chan, London (GB)

(72) Inventors: Robert J. Walters, Alexandria, VA (US); Phillip Jenkins, Washington, DC (US); Maria Gonzalez, Washington, DC (US); Igor Vurgaftman, Severna Park, MD (US); Jerry R. Meyer, Catonsville, MD (US); Joshua Abell, University Park, MD (US); Nicholas Ekins-Daukes, Newbury (GB); Jessica Adams, Chicago, IL (US); Paul Stavrinou, London (GB); Michael K. Yakes, Alexandria, VA (US); Joseph G. Tischler, Alexandria, VA (US); Cory D. Cress, Alexandria, VA (US); Matthew P. Lumb, Alexandria, VA (US); Ngai Chan, London (GB)

(73) Assignee: The Government of the United States of America, as represented by the Secretary of the Navy, Washington, DC (US)

(21) Appl. No.: 14/740,348

(22) Filed: Jun. 16, 2015

Related U.S. Application Data
(62) Division of application No. 13/592,524, filed on Aug. 23, 2012.
(60) Provisional application No. 61/527,677, filed on Aug. 26, 2011.

(51) Int. Cl. H01L 31/0304; H01L 31/036

(52) U.S. Cl. CPC H01L 31/0304; H01L 31/036

(57) ABSTRACT

A multijunction (MJ) solar cell grown on an InP substrate using materials that are lattice-matched to InP. In an exemplary three-junction embodiment, the top cell is formed from In₁₋ₓAlₓAs_{1-y}Sb_{y} (with x and y adjusted so as to achieve lattice-matching with InP, hereafter referred to as InAlAsSb), the middle cell from In_{1-a-b}GaₐAl_{b}As (with a and b adjusted so as to achieve lattice-matching with InP, hereafter referred to as InGaAlAs), and the bottom cell also from InGaAlAs, but with a much lower Al composition, which in some embodiments can be zero so that the material is InGaAs. Tunnel junctions (TJs) connect the junctions and allow photo-generated current to flow. In an exemplary embodiment, an InAlAsSb TJ connects the first and second junctions, while an InGaAlAs TJ connects the second and third junctions.

### CROSS-REFERENCE

This application is a Divisional of and claims the benefit of priority under 35 U.S.C. §120 based on U.S. patent application Ser. No. 13/592,524 filed on Aug. 23, 2012, which in turn is a Nonprovisional of and claims the benefit of priority under 35 U.S.C. §119 based on U.S. Provisional Patent Application No. 61/527,677 filed on Aug. 26, 2011, both of which are hereby incorporated by reference into the present application in their entirety.

### TECHNICAL FIELD

The present invention relates to solar cell technology, particularly to material structures for a multijunction (MJ) solar cell designed to obtain a high photon to electricity conversion ratio.

### BACKGROUND

Solar cells have great promise as a source of renewable energy. Solar cells absorb incident sunlight and convert the light to electricity. The fraction of the incident sunlight intensity that can be converted into useful electrical power is referred to as the conversion efficiency.

Such solar cells can operate under “one-sun” conditions where there is no concentration of the incident light before it enters the cell, or can operate under concentrated conditions, where the solar photons are focused into a smaller area above the solar cell surface.

Multijunction (MJ) solar cells are the state-of-the art, high efficiency solar cell technology, having theoretical efficiencies ˜63% and demonstrated efficiencies>41% under concentrated sunlight. See T. Takamoto, T. Agui, A. Yoshida, K. Nakaido, H. Juso, K. Sasaki, K. Nakamora, H. Yamaguchi, T. Kodama, H. Washio, M. Imaizumi, and M. Takahashi, “World's Highest Efficiency Triple-Junction Solar Cells Fabricated by Inverted Layers Transfer Process,” Proc. 35th IEEE Photovoltaic Specialists Conference (2010), pp. 412-417.

An MJ solar cell consists of semiconductor layers grown sequentially on top of each other to form two or more p-n junctions. Maximum efficiency of the solar cells is achieved when the band gaps of the various constituent layers are well matched to the incident solar spectrum.

A major technical challenge for MJ solar cells is growing the multi-layered stack with high crystalline quality. High crystalline quality is most easily achieved when the materials are grown lattice-matched to the growth substrate. Lattice-mismatched growth generally leads to high densities of dislocations and other defects that short the device and/or increase the parasitic non-radiative decay rate for the electron-hole pairs generated by the sunlight.

Scientists at the National Renewable Energy Laboratory (NREL) have developed MJ solar cells formed from lattice-matched InGaP/GaAs/Ge grown on GaAs or Ge substrates that achieved 30% efficiency with unconcentrated illumination. See K. A. Bertness, S. R. Kurtz, D. J. Friedman, A. E. Kibbler, C. Kramer, and J. M. Olson, “29.5% Efficient GaInP/GaAs Tandem Solar Sells” Appl. Phys. Lett. 65 (8), pp. 989-991 (1994). However, the ultimate efficiency of the lattice-matched InGaP/GaAs/Ge technology is limited because the band gaps for the relatively small number of available materials lattice-matched to Ge and GaAs do not provide adequate coverage of the full solar spectrum.

Therefore, continued MJ solar cell development has turned to lattice-mismatched materials in an attempt to attain materials with a wider range of band gaps. For example, lattice mismatched MJ solar cells are currently under development at NREL. See, e.g., M. W. Wanlass, S. P. Ahrenkiel, R. K. Ahrenkiel, D. S. Albin, J. J. Carapellal, A. Duda, J. F. Geisz, S. R. Kurtz, T. Moriarty, R. J. Wehre, and B. Wernsman, “Lattice-mismatched approaches for high-performance, III-V photovoltaic energy converters,” Proc. 31^{st} IEEE Photovoltaic Specialists Conference, (2005) pp. 530-535. The highest performance has been achieved with lattice mismatched materials that are grown in an inverted fashion, where the higher band gap layer is grown closest to the substrate and each subsequent layer having a smaller band gap. The final device, formed by removing the active layers from the substrate, is referred to as an inverted metamorphic (IMM) solar cell. IMM solar cells have achieved efficiencies in excess of 40% under concentrated illumination. Id.

However, dislocations that form during the mismatched material growth are a fundamental limitation of the IMM technology that ultimately limits the device performance. While substantial progress in devising mismatched growth methodologies has enabled IMM solar cells to achieve record-breaking efficiencies, their realistically achievable maximum efficiency is ˜38% (for 1 sun illumination).

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a lattice-matched MJ solar cell grown on an InP substrate using materials that are lattice-matched to InP.

An exemplary embodiment of a solar cell in accordance with the present invention comprises three p-n junctions formed on an InP substrate. In this exemplary embodiment, the top cell (first junction) is formed from In₁₋ₓAlₓAs_{1-y}Sb_{y} (hereafter referred to as InAlAsSb), with x and y adjusted so as to achieve lattice-matching with InP; the middle cell (second junction) is formed from In_{1-a-b}GaₐAl_{b}As (hereafter referred to as InGaAlAs), with a and b adjusted so as to achieve lattice-matching with InP; and the bottom cell (third junction) also is formed from InGaAlAs (In_{1-d-c}Ga_{d}Al_{c}As), but with a much lower Al composition than in the middle cell. Tunnel junctions (TJs) connect the junctions and allow photo-generated current to flow. In an exemplary embodiment, an InAlAsSb TJ connects the first and second junctions, while an InGaAlAs TJ connects the second and third junctions.

The InAlAsSb material can achieve direct band gaps ranging from 1.6 to 1.8 eV, and the InGaAlAs material can achieve band gaps ranging from 0.74 to 1.4 eV. In some embodiments, multiple strain-balanced quantum wells can be grown between the n and p layers in one or more junctions to extend the gap to 0.7 eV and below.

In other embodiments, other materials lattice-matched to InP can be used for one or more of the junctions or TJs. For example, in some embodiments, InGaAsP can be used for the junctions rather than InGaAlAs to achieve band gaps less than 1.4 eV.

In some embodiments, an MJ solar cell in accordance with the present invention can comprise more than three junctions, the combined band gaps of the junctions being optimized to maximize the conversion efficiency of the cell, the material compositions being engineered to achieve the optimum band gap combination.

In some embodiments, an MJ solar cell in accordance with the present invention can include a quantum well superlattice between the emitter and base layers of any of the junctions. In an exemplary embodiment, InGaAs/InGaAlAs quantum wells are included on the bottom junction to extend the absorption range of that junction whilst maintaining lattice match.

In some embodiments, two junctions may be formed from material of the same band gap, referred to as a “split cell”. Splitting one of the junctions in this fashion allows a significant voltage increase, and if the uppermost junction is suitably thin, the current generation can be split equally between the two junctions of the split cell. In an exemplary embodiment, the top InAlAsSb junction can be replaced by a split InAlAs (1.46 eV) top cell connected via a tunnel junction. In such an embodiment, the middle cell band gap is typically much lower than in the case of a single top cell, while the bottom cell band gaps remain the same. As the band gap of InAlAs is considerably lower than that of lattice-matched InAlAsSb, the short-circuit current is only marginally decreased.

### BRIEF DESCRIPTION OF THE DRAWINGS

FIG. 1 depicts an exemplary embodiment of a multijunction (MJ) solar cell formed on an InP substrate in accordance with one or more aspects of the present invention.

FIG. 2 depicts an exemplary embodiment of a MJ solar cell formed on an InP substrate incorporating the “split-junction” for the top junction.

FIG. 3 is a plot illustrating the exponential decay of radiative efficiency Tad as a function of lattice mismatch to GaAs.

FIG. 4 is a plot of band gap as a function of lattice constant for various binary and ternary alloys which may be used in a multijunction solar cell in accordance with one or more aspects of the present invention.

FIGS. 5A and 5B are contour plots showing efficiencies exhibited for various combinations of bottom and middle junction energy gaps with a top junction having a fixed energy gap value, with FIG. 5A showing the efficiencies for AM1.5D, 500× concentrated illumination and FIG. 5B showing the efficiencies for atmospheric mass AM0 and one sun illumination.

FIG. 6 contains plots of calculated conversion efficiency η projected for MJ solar cells having top, middle, and bottom junctions having various combinations of energy gaps for solar cells under 500×AM1.5D and 1 sun AM0 irradiation assuming a radiative efficiency η_{rad} of 22%.

FIGS. 7A and 7B further illustrate aspects of the conversion efficiencies shown in FIG. 7 and where FIG. 7A illustrates the optimum combination of energy gaps as determined by the inventors and FIG. B illustrates aspects of energy bands and materials suitable for use in an exemplary embodiment of an MJ solar cell on an InP substrate in accordance with the present invention.

FIG. 8 is a plot illustrating the band structure and corresponding electron and heavy-hole wavefunctions for an exemplary InGaAs/InGaAs QW structure in accordance with aspects of some embodiments of the present invention.

FIGS. 9A and 9B further illustrate aspects of the energy bands, lattice-matched materials, and the exemplary embodiment of an MJ solar cell on an InP substrate in accordance with the present invention shown in FIG. 1, with FIG. 9A illustrating aspects of exemplary energy bands and lattice-matched materials and FIG. 9B illustrating how those energy bands and lattice-matched materials are embodied in the exemplary MJ solar cell shown in FIG. 1.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

The present invention is a multijunction (MJ) solar cell having a structure that is lattice-matched to the cell's host substrate. As described above, an MJ solar cell is a multi-layered, semiconductor device that absorbs solar light and converts a certain fraction of the incident solar intensity to electricity (given by the conversion efficiency q). For a semiconductor with a certain energy gap, the fundamental limit on the conversion efficiency is determined by the fraction of the photogenerated electron-hole pairs that recombines radiatively (with the resulting photons escaping from the device) before being collected into the contacts to produce electricity. The existence of radiative recombination is thermodynamically unavoidable if photon absorption is to take place. The presence of any additional non-radiative recombination reduces the conversion efficiency below the fundamental radiative limit, with the ratio between radiative and total recombination rates referred to here as the radiative efficiency η_{rad}.

In an MJ solar cell, the conversion efficiency is further optimized by absorbing different parts of the solar spectrum in successive semiconductor layers having different band gaps so that the energy of the absorbed photons that is in excess of the energy gap (usually dissipated into heat) is minimized. By choosing the set of band gaps to match the incident solar spectrum, very high photon to electricity conversion efficiencies can be achieved. MJ solar cells can be applied in terrestrial systems with the highest efficiencies being achieved with a concentrator system where the sunlight is focused onto the solar cell and in space systems.

The present invention also includes a computer-implemented modeling method for determining an optimum combination of band gaps to maximize the conversion efficiency of an MJ solar cell and to determine an optimum combination of materials for the solar cell that would achieve such an optimum band gap combination. As will be appreciated by one skilled in the art, a method for determining an optimum combination of band gaps to maximize the conversion efficiency of an MJ solar cell and to determine an optimum combination of materials for the solar cell that would achieve such an optimum band gap combination in accordance with these aspects of the present invention can be accomplished by entering data including data of desired radiative efficiencies and possible band gap ranges into one or more general or special-purpose computers and executing one or more sequences of instructions contained in computer-readable program code read into a memory of such one or more general or special-purpose computers configured to execute the instructions.

An MJ solar cell in accordance with the present invention comprises a heterostructure formed on an InP substrate, the heterostructure containing material layers lattice-matched to InP and forming a plurality of p-n junctions where photons are absorbed to generate current in the solar cell, and also containing tunnel junctions that connect one junction to the next in series. When a photon is absorbed in one p-n junction, an electron hole pair is created which are separated by the junction electric field. The charge carriers then diffuse through the remainder of the MJ stack and are collected at the electrical contacts. The tunnel junctions allow the charge carriers to pass from one p-n junction to the next. The number of charge carriers collected defines the solar cell efficiency. The efficiency is calculated as the measured electrical power produced by the solar cell divided by the amount of solar energy incident upon the cell.

In some embodiments of an MJ solar cell in accordance with the present invention, the InP lattice-matched material layers are combined with quantum wells and superlattices that are strain-balanced to InP to form the solar cell. True lattice-matched materials are those having a lattice constant that is the same or nearly the same as InP, while strain-balanced materials combine tensile-strained and compressive-strained constituents such that their net strains compensate one another, with the strained constituents being sufficiently thin that no relaxation or excessive defect generation is expected to occur in any given layer.

In the present disclosure, the term “lattice-matched” will be used to describe both true lattice-matched and strain-balanced regions.

InP is a widely-used substrate for producing electronic and optoelectronic semiconductor devices based on lattice-matched heterostructures, quantum wells, and superlattices. The technology for growing heterostructures on InP by molecular beam epitaxy or metalorganic chemical vapor deposition, and for high-volume processing has reached a high level of maturity that is suitable for commercial production. For the MJ solar cells disclosed in this invention, InP has the advantage of offering lattice-matched materials spanning a wider range of band gaps than any other substrate that is both commonly-available and manufacturable.

Previous InP-based designs have either omitted a high-gap top-cell material that only enables a double junction solar cell to be made, see M. W. Wanlass, J. S. Ward, K. A. Emery, A. Duda, and T. J. Coutts, “Improved Large-Area, Two-terminal InP/Ga_{0.47}In_{0.53}As Tandem Solar Cells,” Proc. IEEE Photovoltaic Specialists Conference 1994, p. 1717, or have been restricted to relatively low band gaps, see M. S. Leite, R. L. Woo, W. D. Hong, D. D. Law, and H. A. Atwater, “Wide-band gap InAlAs solar cell for an alternative multijunction approach,” Appl. Phys. Lett. 98, 093502 (2011).

The present invention overcomes the limitations of the prior designs.

As described in more detail below, the inventors herein developed the present invention using detailed modeling to identify band gap combinations that are predicted to achieve optimum conversion efficiencies and materials and material combinations having the desired band gaps.

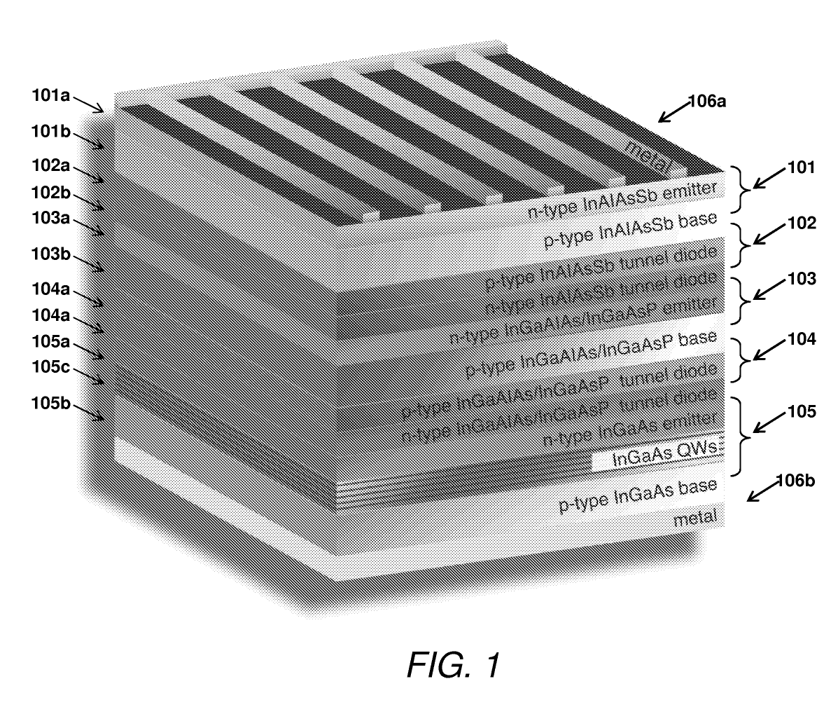

An exemplary embodiment of an MJ solar cell in accordance with one or more aspects of the present invention is illustrated in FIG. 1. It should be noted that although the exemplary MJ solar cell illustrated in FIG. 1 is a three-junction configuration, as described in more detail below, other embodiments of an MJ solar cell in accordance with the present invention can contain more than three junctions.

As shown in FIG. 1, and as described in more detail below, an MJ solar cell in accordance with the present invention is a heterostructure formed on an InP substrate (not shown). The heterostructure includes top, middle, and bottom p-n junctions 101, 103, and 105, respectively, formed from n-type emitter layers 101a/103a/105a and p-type base layers 101b/103b/105b. The top and middle p-n junctions are separated by tunnel junction 102 formed from p-type tunnel diode layer 102a and n-type tunnel diode layer 102b and the middle and bottom p-n junctions are separated by tunnel junction 104 formed from p-type tunnel diode layer 104a and n-type tunnel diode layer 104b. In addition, in the embodiment shown in FIG. 1, bottom p-n junction 105 further includes a quantum well superlattice 105c situated between emitter and base layers 105a and 105b of p-n junction 105. The MJ solar cell is connected to top and bottom metal contacts 107a and 107b, respectively.

In accordance with the present invention, the p-n and tunnel junctions in the MJ solar cell depicted in FIG. 1 are formed from materials that are lattice-matched (i.e., either true lattice-matched or strain-balanced as described above) to the InP substrate.

One key to the invention is exploiting Sb-containing alloys and the insight into their properties gained from the expertise of the inventors at the Naval Research Laboratory with this and related Sb-containing materials systems. See I. Vurgaftman, J. R. Meyer, and L. R. Ram-Mohan, “Band parameters for III-V compound semiconductors and their alloys,” J. Appl. Phys. 89, 5815 (2001) (“Vurgaftman 2001); I. Vurgaftman, E. H. Aifer, C. L. Canedy, J. G. Tischler, J. R. Meyer, J. H. Warner E. M. Jackson, G. Hildebrandt and G. J. Sullivan, “Graded band gap for dark-current suppression in long-wave infrared W-structured type-II superlattice photodiodes,” Appl. Phys. Lett. 89, 121114 (2006) (“Vurgaftman 2006); and I. Vurgaftman, C. L. Canedy, C. S. Kim, M. Kim, W. W. Bewley, J. R. Lindle, J. Abell and J. R. Meyer, “Mid-infrared interband cascade lasers operating at ambient temperatures,” New J. Phys. 11, 125015 (2009) (“Vurgaftman 2009”), all of which are hereby incorporated by reference into the present disclosure in their entirety.

Thus, in an exemplary embodiment such as that illustrated in FIG. 1, top junction 101 is formed from In₁₋ₓAlₓAs_{1-y}Sb_{y} (hereafter referred to as InAlAsSb) n and p layers 101a/101b, where y is between 0.15 and 0.3 and x=(0.4748+1.0602y)/(1−0.1342y). The inventors of the present invention have found that such values of x and y permit that InAlAsSb top layer to achieve lattice-matching with the InP substrate. The middle junction 103 is formed from In_{1-a-b}GaₐAl_{b}As (hereafter referred to as InGaAlAs) n and p layers 103a/103b, where b is between 0.30 and 0.36 and a≈(0.4656−0.9806b), both a and b being adjusted so as to achieve lattice-matching with the InP substrate. The bottom junction 105 is formed from In_{1-d-c}Ga_{d}Al_{c}As n and p layers 105a/105b, where d and c are also adjusted to achieve lattice-matching with InP, with d≈(0.4656-0.9806c), and where c is much lower than b, typically between about 0 and about 0.10. As described in more detail below, in some embodiments the material in the bottom cell can comprise InGaAs quantum wells embedded into In_{1-d-c}Ga_{d}Al_{c}As with c between 0.05 and 0.10. As described in more detail below, these materials were identified using the modeling method in accordance with the present invention and were specifically chosen to achieve band gaps of about 1.6-1.9 eV, 1.2 eV, and 0.74 eV in the top, middle, and bottom cells, respectively, band gaps which according to the inventors' modeling method will enable conversion efficiencies of ˜38% under 1 sun (AM0) illumination and ˜51% under concentrated (AM1.5D) illumination.

Tunnel junctions (TJs) 102 and 104 connect the p-n junctions and allow photo-generated current to flow. Thus, in the exemplary embodiment shown in FIG. 1, InAlAsSb TJ 102 formed from p- and n-type tunnel diodes 102a/102b connects the first and second junctions 101 and 103, while an InGaAlAs TJ 104 formed from p- and n-type tunnel diodes 104a/104b connects the second and third junctions 103 and 105. More junctions can be added by adding more layers of the same material systems but of differing stoichiometry to achieve band gaps between 0.7 and 1.8 eV.

The InAlAsSb material used to form top cell p-n junction 101 and TJ 102 can achieve direct band gaps ranging from 1.6 to 1.9 eV, and the InGaAlAs material used to form middle and bottom cell p-n junctions 103 and 105 and TJ 104 can achieve band gaps ranging from 0.74 to 1.45 eV. In addition, in the embodiment shown in FIG. 1, multiple strain-balanced quantum wells 105c can be grown to extend the band gap in bottom cell 105 to 0.7 eV and below. For example, a 120 Å In_{0.62}Ga_{0.38}As/180 Å In_{0.46}Ga_{0.28}Al_{0.26}As is estimated to have a room-temperature gap of 0.708 eV. This wide range of band gaps available with lattice-matched materials is the major strength of this invention.

For operation, electrical contact is made to the top and bottom metal contacts 106a/106b of the device, and the device is placed in sunlight. The absorbed incident sunlight generates a voltage and an electrical current. The current is collected through the electrical contacts, and when the electric leads are connected to an external load, power can be extracted from the device.

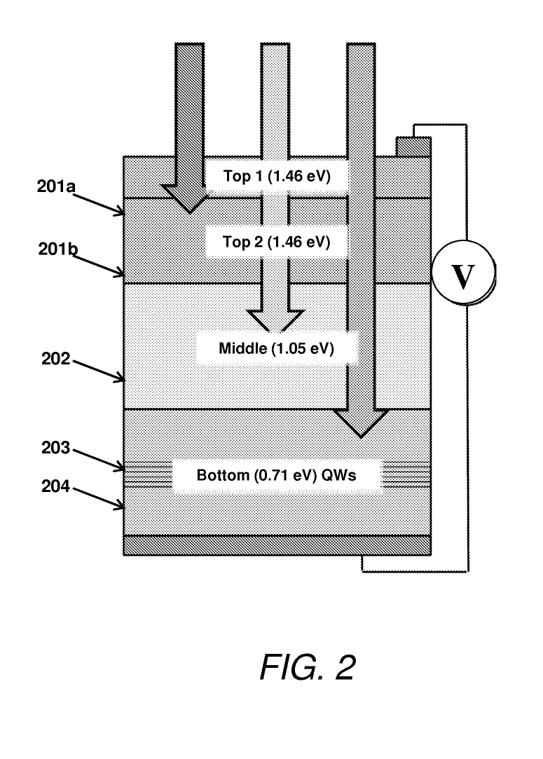

FIG. 2 illustrates aspects of an alternative embodiment of an MJ solar cell in accordance with the present invention. In the embodiment illustrated in FIG. 2, two junctions may be formed from material of the same band gap, referred to as a “split cell”. Splitting one of the junctions in this fashion allows a significant voltage increase, and if the uppermost junction is suitably thin, the current generation can be split equally between the two junctions of the split cell. In such a case, the middle cell band gap is much lower than in the single top cell embodiment, while the bottom cell band gap is not significantly changed. For example, in the embodiment illustrated in FIG. 2, an MJ solar cell in accordance with these aspects of the present invention can include a bottom InGaAs cell 203 having a number of QWs 204 therein and having a band gap of 0.71 eV, a middle InGaAlAs cell 202 having a band gap of 1.05 eV, which requires a value of b of about 0.23, and a top InAlAsSb junction replaced by a split InAlAs (1.46 eV) top cell 201a/201b connected via a tunnel junction. As the band gap of InAlAs is considerably lower than that of lattice-matched InAlAsSb, the short-circuit current is only marginally decreased.

The device can be operated under one-sun conditions where there is no concentration of the incident light before it enters the solar cell. The incident sunlight can also be concentrated, i.e., the solar photons are focused into a smaller area above the solar cell surface.

As described in more detail below, detailed modeling performed by the inventors herein projects that this device has a realistically achievable efficiency over 50% under concentrated illumination.

Prior to this invention, no suitable top cell material had been identified or discussed in the literature for InP-based MJ solar cells and modeling approaches were based on very idealized models without predictive power of recombination parameters. See G. Letay, A. W. Bett, “EtaOpt—a program for calculating limiting efficiency and optimum band gap structure for multi-band gap solar cells and TPV cells,” Proceedings of the 17th European Photovoltaic Solar Energy Conference, Munich, Germany, pp. 178-181 (2001).

As described in more detail below, the optimal band gaps and materials used for all three absorbing regions of the triple-junction solar cell were determined by the inventors of the present invention by creating and applying a novel model and optimization procedure for maximizing the net MJ solar cell conversion efficiency.

An important innovation embodied in this aspect of the present invention is its implementation of the radiative efficiency concept for each subcell. The radiative efficiency η_{rad} is defined as the ratio of the current density induced by radiative recombination in the absorbing cell material to the cell's total current density when the short-circuit current density is 30 mA/cm². While the desired radiative component of the current density is fundamental and inevitable in any absorbing material, the total current density includes additional parasitic nonradiative components that most often originate in the depletion region of the subcell's p-n junction. The methodology used in accordance with this aspect of the present invention further makes the realistic assumption that almost ideal absorption can be achieved in each component junction, with radiative and non-radiative recombination described by an empirical estimate that gives good fits over a wide range of materials. See N. L. A. Chan, N. J. Ekins-Daukes, J. G. J. Adams, M. P. Lumb, M. Gonzalez, P. P. Jenkins, I. Vurgaftman, J. R. Meyer, R. J. Walters, “Optimal Band gap Combinations—Does Material Quality Matter?”, IEEE Journal of Photovoltaics, Vol. 2, No. 2, pp. 202-208 (2012), the entirety of which is incorporated by reference into the present disclosure.

In order to obtain realistic values of the radiative efficiency for use in the modeling, the inventors studied a wide variety of solar cells whose absorbing regions that were grown on both lattice-matched and lattice-mismatched substrates. When lattice mismatch is present, strain relaxation of the strain and the associated increase in the density of nonradiative recombination centers is known to substantially shorten the carrier lifetimes. This in turn leads to higher defect-induced dark current densities, and consequently lower radiative efficiencies as defined above. For lattice-matched GaAs, InGaP, and InGaAs junctions, the radiative efficiencies in the range of 20-27% are typically obtained, assuming a fixed short current density of 30 mA/cm².

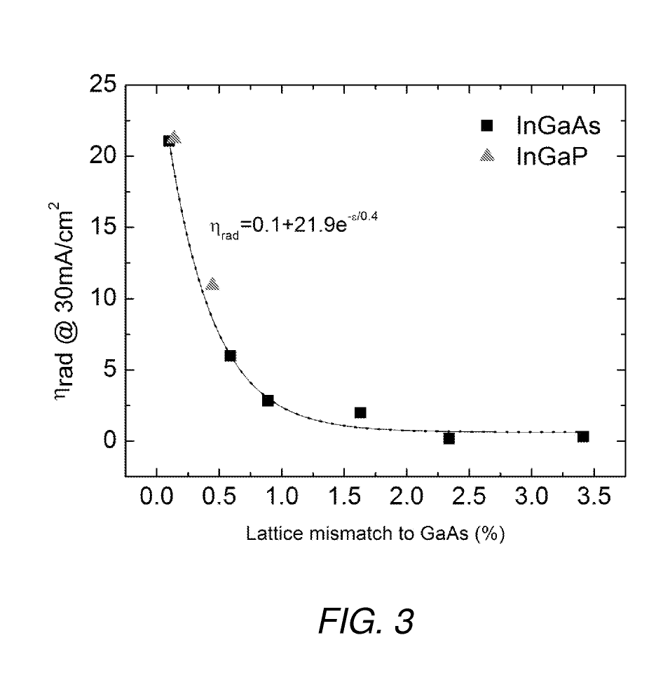

On the other hand, the inventors found that for lattice-mismatched devices, the radiative efficiency η_{rad} decreases with the magnitude of the lattice mismatch in a roughly exponential manner, as depicted in the plot shown in FIG. 3 for InGaAs and InGaP. That is, η_{rad}=η_{b}+η₀e^{-ε/γ}, where η_{b} and η₀ are constants (η_{b}+η₀ is the value for a lattice-matched device), ε is the percentage of lattice mismatch with the substrate, and γ is the exponential decay parameter. Our fitting yielded a decay parameter of γ ≈0.4%.

In this manner, the dependence of the radiative efficiency on the lattice mismatch is automatically incorporated into the model. An advantage of this approach is that it fully accounts for the negative impact of lattice-mismatched growth on the predicted power conversion efficiency. It thereby avoids the incorrect conclusion that one can optimize the efficiency simply by manipulating the band gaps of the various subcells without regard to whether the seemingly-optimal configuration is reached by employing strained materials that cannot be grown without inducing high densities of non-radiative defects.

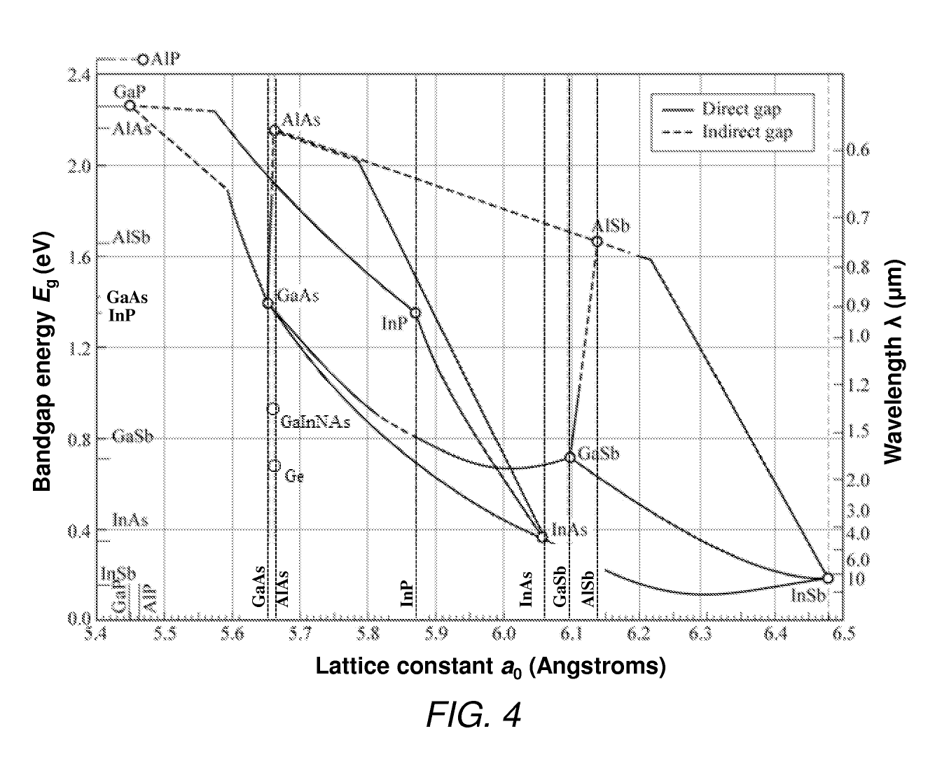

FIG. 4 is a plot showing direct and indirect band gaps as a function of lattice constant for various semiconductor binary and ternary alloys. The vertical dashed lines on the chart show commonly available growth substrates, in particular GaAs, InP, InAs, and GaSb, such that this figure indicates the band gaps that can be achieved lattice-matched to these substrates. It must be remembered that materials with indirect band gaps are unsuitable as solar cell absorbers because absorption at their indirect gap is too weak to be useful whereas absorption at their direct gap is inefficient because the photoexcited electrons quickly relax to the indirect valleys where the induced photovoltage is lower. Considering only direct gap binaries and ternary alloys (the solid curves), we find that the material system lattice-matched to GaAs do not offer any band gaps intermediate between Ge at 0.7 eV and GaAs at 1.4 eV, whereas the material systems lattice-matched to GaSb or InAs do not offer any band gaps above about 1.0 eV. The inventors have found that there are significantly more band gaps available with InP substrates, but until now no material was identified to achieve a direct band gap above 1.45 eV. This is also the conclusion one draws if the chart in FIG. 4 is examined in a straightforward manner. However, a better choice with larger direct band gap becomes available when the quaternary alloy InAlAsSb lattice-matched to InP is considered.

A key finding of the inventors' model is that it is highly beneficial to employ only lattice-matched constituent materials in all of the subcells, if possible. The inventors herein based their modeling on a series connected, two-terminal, three-junction cell assuming a realistic radiative efficiency value for lattice-matched material, (see R. R. King, D. Bhusari, A. Boca, D. Larrabee, X.-Q. Liu, W. Hong, C. M. Fetzer, D. C. Law, and N. H. Karam, “Band gap-voltage offset and energy production in next-generation multijunction solar cells,” Prog. Photovolt: Res. Appl. (2010)), a 98% quantum efficiency for above band gap photons, and various spectral conditions. The results of this modeling provide a more realistic estimate of the band gap requirements for attaining efficiencies in excess of 50% than were obtained using previous models. One skilled in the art will readily recognize, however, that other embodiments of an MJ solar cell on an InP substrate, for example, those using different InP lattice-matched (as described above to include strain-balanced) materials and/or different heterostructures having more than three p-n junctions, may also be identified using different model parameters. In addition, modeling may be performed to identify appropriate materials for use with other substrates, such as GaAs, InP, InAs, and GaSb. All such other embodiments are contemplated to be within the scope of the invention described and claimed herein.

This aspect of the present invention provides a method for finding an optimum set of materials for an MJ solar cell heterostructure to achieve a maximum solar conversion efficiency, where the suitability of any particular candidate material for use in the heterostructure is quantified by the material's radiative efficiency.

Thus, in a method for finding such an optimum set of materials in accordance with the present invention, a set of candidate materials, each material having an associated band gap (or a range of attainable band gaps for alloys) and a level of lattice mismatch to a desired host substrate is evaluated, where the evaluation includes a determination of the radiative efficiency of each material η_{rad} as a function of its lattice mismatch to the host substrate. Such an evaluation can be embodied in the form of a plot such as that shown in FIG. 3 discussed above or can be a simple mathematical evaluation without a plot being generated.

In a next step, an optimum combination of materials for each junction of the MJ solar cell on a given host substrate is identified, where the optimum combination of band gaps and radiative efficiencies for each material maximizes the overall solar conversion efficiency η of the solar cell subject to the constraints on the energy gaps and radiative efficiencies determined in the previous step This step is accomplished using the mathematical model described in detail below and in general takes the form a multi-parameter optimization, where the number of parameters is twice the number of junctions (since each junction is characterized by a material with a given band gap and a certain value of the radiative efficiency).

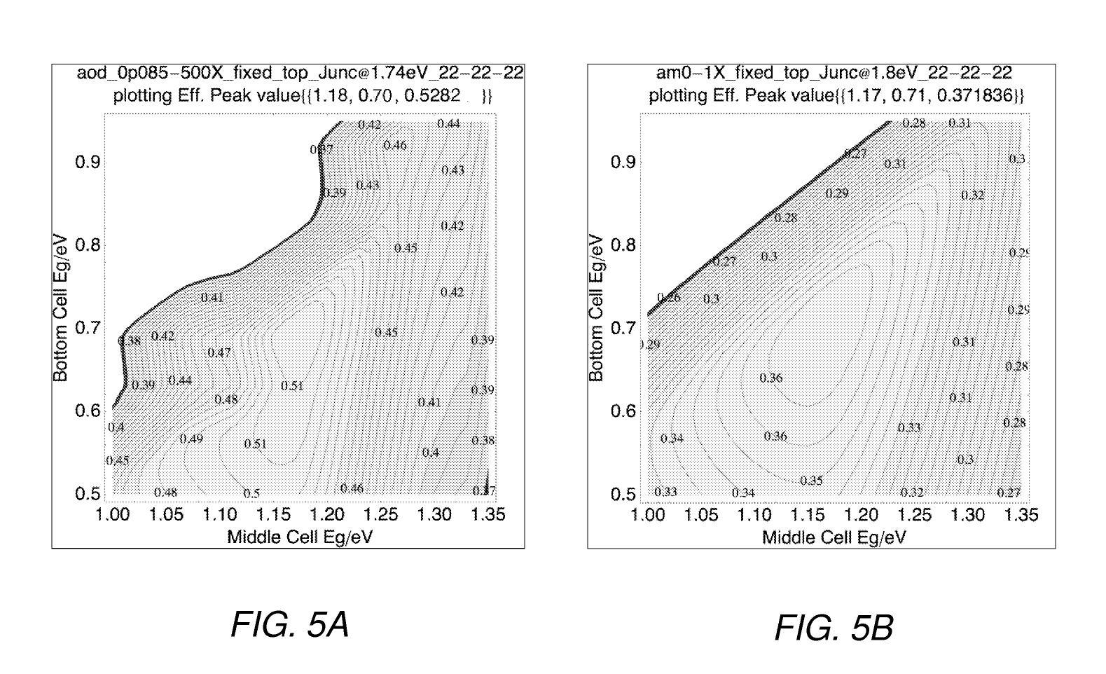

In accordance with the present invention, the optimum combination of materials for an MJ solar cell on a particular substrate can also be found by setting a band gap value E_{g} and a radiative efficiency η_{rad} of one of the top, bottom, or middle cells of the MJ solar cell at a first fixed value and employing different materials with their corresponding band gaps and radiative efficiencies in each of the other cells and calculating a solar conversion efficiency at each such combination, and then setting the fixed band gap value at a second fixed value, varying the other band gaps and calculating the conversion efficiency for those band gap combinations, and so on. In this way, a set of top, bottom, and middle band gaps that produce a maximum solar conversion efficiency can be identified. The results of this analysis can be plotted in contour plots such as those shown in FIGS. 5A and 5B described below, although such a plotting step is not necessary and can be omitted.

If a ternary, quaternary, or other alloy is used in the optimization process, the specific stoichiometry needed to realize the energy gap determined in the previous steps is identified.

Additional details regarding the method for determining an optimum set of materials for an MJ solar cell in accordance with this aspect of the present invention are provided below.

In accordance with this aspect of the present invention, for given candidate energy gaps of the individual subcells (three, four or more junctions can be easily handled), the model first calculates the voltage drops over each cell exposed to the solar spectrum, subject to the condition that the same current must flow through every cell.

The modeling was performed assuming the MJ device to be multiple diodes connected in series. The recombination current in each diode can be approximated using the standard two-diode model. One component, J₀₁, describes bi-molecular recombination, which we assume to be radiative, while the other mono-molecular component, J₀₂, describes non-radiative Shockley-Read-Hall (SRH) recombination in the depletion region:

J_{dark}(V)=J₀₁(e^{(qV/kT)}−1)+J₀₂(e^{(qV/2kT)}−1) (1)

In Equation (1), we neglect non-radiative recombination in the neutral regions, which requires the non-radiative lifetime there to be long when compared to the radiative lifetime. J₀₁ is a fundamental property of a given semiconductor, fixed by the joint-density of states and oscillator strength. It can be estimated by assuming that the onset of absorption (and emission) occurs at the band-gap energy, and that the probability of absorption (and emission) is unity. This enables the internal, isotropic emission from a semiconductor of refractive index n to be described by a generalized form of the Planck equation:

$$N = \frac{2 π {n}^{2}}{4 {π}^{3} {ℏ}^{3} {c}^{2}} {\int }_{{E}_{g}}^{∞} \frac{{E}^{2}}{{e}^{( ( E - μ ) / kT )} - 1} d E \qquad ( 2 )$$

where N is the emitted photon flux density, E is the photon energy and μ is the difference in electrochemical potential between the electron and hole populations.

Using Equation (2), applying the Boltzmann approximation, and integrating, we obtain

$$N = \frac{2 π {n}^{2}}{4 {π}^{3} {ℏ}^{3} {c}^{2}} {e}^{( - {E}_{g} / kT )} kT ( {E}_{g}^{2} + 2 {E}_{g} kT + 2 {k}^{2} {T}^{2} ) {e}^{( q μ / kT )} . \qquad ( 3 )$$

Thus, J₀₁ can be estimated by converting the photon flux into current and assuming the application of a bias V=μ:

$${J}_{01} = \frac{q 2 π {n}^{2}}{4 {π}^{3} {ℏ}^{3} {c}^{2}} {e}^{- {E}_{g} / kT} kT ( {E}_{g}^{2} + 2 {E}_{g} kT + 2 {k}^{2} {T}^{2} ) . \qquad ( 4 )$$

The total current through a solar cell can be expressed:

J_{TOTAL}(V)=J_{sc}−J₀₁(e^{(qV/kT)}−1)−J₀₂(e^{(qV/2kT)}−1) (5)

where J_{sc} is assumed to be equal to the electron charge q times the photon flux per unit energy from a given solar spectrum dΦ/d(ω) integrated over all photon energies ω>E_{g}, and the sign of the current is chosen so that positive currents correspond to generation. Using Equation (5), the J_{TOTAL}V product can be maximized, and the maximum conversion efficiency 11 is computed as the ratio of the J_{TOTAL}V product to the integral of ωdΦ/d(ω) over all energies ω.

Within the assumption of a fully radiative J₀₁ term, the radiative efficiency of the device, as defined above, near the operating bias can be written as:

$${η}_{rad} ( V ) = \frac{{J}_{01} ( {e}^{( qV / kT )} - 1 )}{{J}_{01} ( {e}^{( qV / kT )} - 1 ) + {J}_{02} ( {e}^{( qV / 2 kT )} - 1 )} . \qquad ( 6 )$$

As discussed above, η_{rad} can be regarded as a measure of the device quality, related to the presence of defects and other recombination centers. It is evident from Equation (6) that the radiative efficiency is a strong function of device voltage V. To compare materials with different band-gap energies, we choose an arbitrary level of injection corresponding to a J_{sc} of 30 mA/cm² (close to the short-circuit current density of a single-junction GaAs solar cell). Under open-circuit conditions, i.e. J_{TOTAL}(V)=0, we can define the radiative efficiency for a given cell as:

$${η}_{rad} ( {V}_{oc} ) = \frac{{J}_{01} ( {e}^{( {qV}_{ov} / kT )} - 1 )}{{J}_{sc}} \qquad ( 7 )$$

where J_{sc}=30 mA/cm². Further, J₀₂ can be expressed in terms of J₀₁, V_{oc}, and η_{rad} through:

$${J}_{02} = \frac{{J}_{01} ( {e}^{( {qV}_{oc} / kT )} - 1 ) ( \frac{1}{{η}_{rad} ( {V}_{OC} )} - 1 )}{( {e}^{( {qV}_{oc} / 2 k T )} - 1 )} . \qquad ( 8 )$$

Using the plot of radiative efficiency η_{rad} versus lattice mismatch shown in FIG. 3, the inventors determined that a value of η_{rad}=22% is reasonable for good quality, lattice-matched materials, though it should be noted that in other cases other values for η_{rad} may be appropriate. Using this value for η_{rad}, a set of contour plots were constructed so that the maximum solar cell efficiency could be found under different spectral conditions and band gap combinations. In constructing the contour plots, the model holds the band gap for one cell, typically the top cell, at a fixed value, varies the band gaps for the middle and bottom cells, and determines a conversion efficiency for each combination of top, middle, and bottom cell band gaps.

As noted above, FIGS. 5A/5B and 6 illustrate aspects of the modeling used by the inventors in developing a three-junction MJ solar cell in accordance with the present invention. See M. Gonzalez, N. Chan, N. J. Ekins-Daukes, J. G. J. Adams, P. Stavrinou, I. Vurgaftman, J. R. Meyer, J. Abell, R. J. Walters, C. D. Cress, and P. P. Jenkins, “Modeling and Analysis of Multijunction Solar Cells,” Proceedings of the SPIE, Volume 7933, pp. 79330R-79330R-12 (2011); and R. J. Walters, M. Gonzalez, J. G. Tischler, M. P. Lumb, J. R. Meyer, I. Vurgaftman, J. Abell, M. K. Yakes, N. Ekins-Daukes, J. G. J. Adams, N. Chan, P. Stavrinou, and P. P. Jenkins, “Design of an Achievable, All Lattice-Matched Multijunction Solar Cell Using InGaAlAsSb,” Photovoltaic Specialists Conference (PVSC), 2011 37th IEEE (2011), the entirety of both of which are hereby incorporated into the present disclosure.

FIGS. 5A and 5B contain exemplary contour plots that can be used to find the optimum combination of band gaps for AM1.5D low Aerosol Optical Depth (AOD) spectral conditions (FIG. 5A) and 500× concentrated light for 1-sun AM0 conditions (FIG. 5B). In each of FIGS. 5A and 5B, the top cell band gap was kept constant while the band gaps of the middle and bottom cells were varied, and the resulting conversion efficiency for each combination was plotted.

FIG. 5A shows that for AM1.5D/500× illumination and a top cell band gap of 1.74 eV, a maximum conversion efficiency of over 0.52 can be achieved with combined middle and bottom cell band gaps of 1.18 and 0.7 eV, respectively. Similarly, FIG. 5B shows that in the case of AM0/1× and a top cell band gap of 1.8 eV, a maximum conversion efficiency greater than 0.36 can be achieved with middle and bottom cell band gaps of about 1.17 and 0.71 eV, respectively. Thus, an MJ solar cell having a top cell band gap of about 1.8 eV, a middle cell band gap of about 1.18, and a bottom cell band gap of about 0.7 can achieve efficiencies in excess of 50% under concentrated illumination (AM1.5D/500×) and almost 40% under extraterrestrial illumination (AM0).

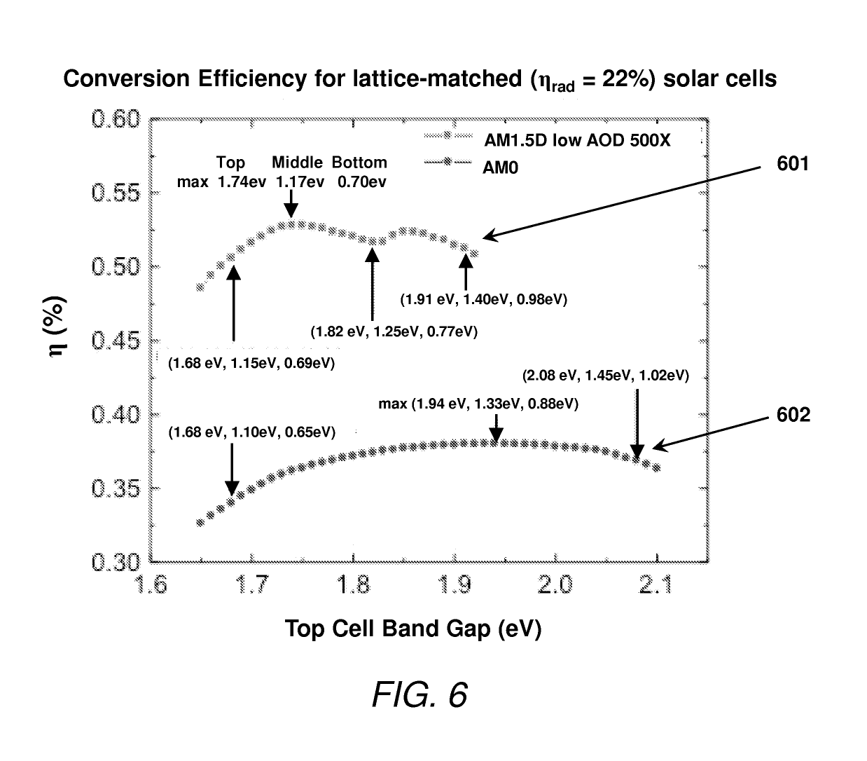

Additional aspects of these contour plots are illustrated in plots 601 and 602 shown in FIG. 6, where each point in the plots in FIG. 6 corresponds to an individual contour plot for which the top cell band gap is fixed and the bottom and middle cell band gaps are varied. The arrows in FIG. 6 indicate the band gap combinations yielding the maximum efficiency for each spectral condition, along with combinations corresponding to a few other points along the curves. As shown in plot 601 in FIG. 6, under AM1.5D low-AOD 500X illumination, the conversion efficiency reaches 52.8% for the optimized bottom, middle, and top cell gaps of 0.70 eV, 1.18 eV, and 1.74, respectively. As shown in plot 602 in FIG. 6, Under AM0 spectral conditions, a maximum efficiency of ˜38% is reached for band gaps of 1.94 eV, 1.33 eV and 0.88 eV, although nearly the same efficiency is achieved for a top-cell band gap of 1.8 eV.

Using this modeling, the inventers were able to identify suitable materials that could satisfy the desired band gap combination to achieve the maximum efficiencies.

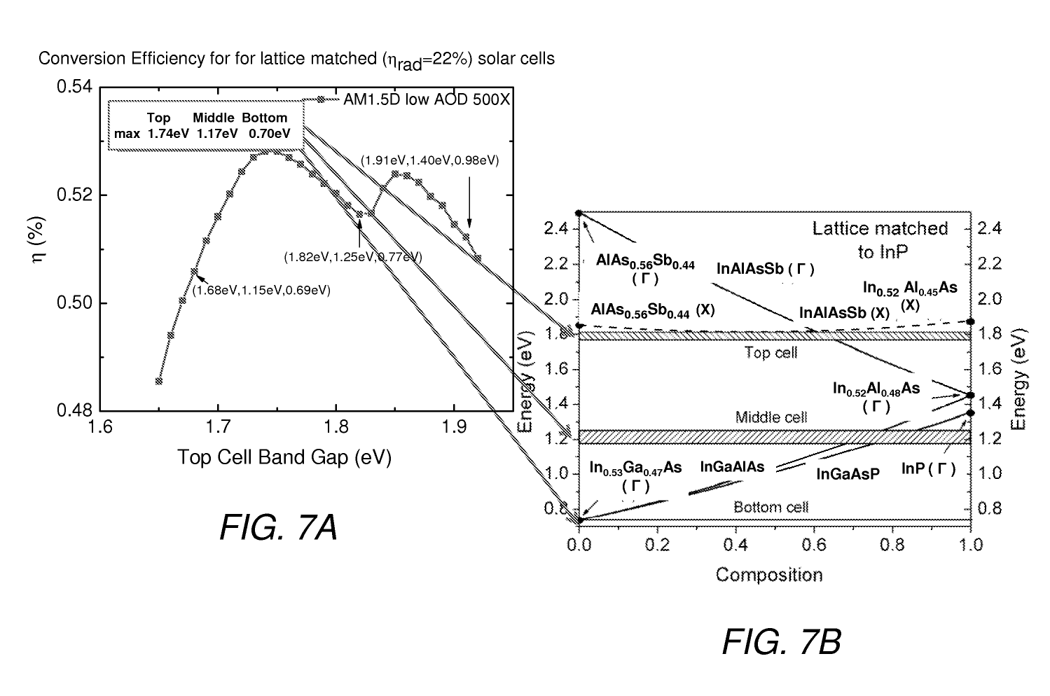

FIGS. 7A and 7B further illustrate aspects of the band gaps and materials identified for an MJ solar cell lattice-matched to InP in accordance with the present invention. FIG. 7A is a close-up of a portion the AM1.5D/500× plot shown in FIG. 6, and as noted above, shows that in a 3-junction solar cell lattice-matched to InP, a maximum conversion efficiency of over 50% can be achieved if a combination of top, middle, and bottom band gaps of 1.74 eV, 1.17 eV, and 0.70 eV is employed.

FIG. 7B illustrates the results obtained by the inventors using an 8-band k.p model, see Vurgaftman 2001, supra, to estimate the energy gaps for various III-V ternary and quaternary alloys lattice-matched to InP, and maps these optimum band gaps to the band gaps of available materials that are lattice-matched to InP.

The plots in FIG. 7B show both direct (Γ-valley) and indirect (in this case, X-valley) band gaps for several quaternary alloys that are lattice-matched to InP. For all of the quaternaries in the figure, the left axis shows one constituent ternary while the right axis shows the other constituent ternary or binary. For a given composition, the various quaternary alloys are constructed by combining the fraction x of the ternary or binary alloy on the right with the fraction 1−x of the ternary alloy on the left. Since the band gaps of the quaternaries generally do not follow a strictly linear interpolation of the compositions, the figure accounts for whatever information is available concerning the bowing of those dependences. The information obtained from the plot in FIG. 7B was used by the inventors to identify suitable materials for use in an MJ solar cell in accordance with the present invention.

It is desirable to maximize the direct (Γ-valley) band gap while assuring that that it is no larger than the indirect X-valley gap. Indirect-gap alloys are unsuitable for high-performance solar cells because they have negligible absorption below the Γ-valley transition and can exhibit a loss of voltage associated with carrier relaxation to the lower X-valley states. Thus, as shown in FIG. 7B, while the X-valley energy gap of AlAs_{0.56}Sb_{0.44} is about 1.85, close to the 1.74 eV optimum top-cell gap, the Γ-valley energy gap of AlAs_{0.56}Sb_{0.44} is over 2.4 eV, a value much higher than the optimum top layer energy gap of 1.74 eV. Because of the limitations of using indirect alloys noted above, AlAs_{0.56}Sb_{0.44} lattice-matched to InP is not a suitable material for use in an MJ solar cell in accordance with the present invention.

On the other hand, the Γ-valley and X-valley for the InAlAsSb quaternary cross at an energy around 1.8 eV with a stoichiometry of In₀₃Al_{0.7}As_{0.83}Sb_{0.17}, suggesting that strong absorption by such a 1.8 eV material should be achievable. In practice, since some of the band parameters used in FIG. 7B are somewhat uncertain, we expect to be able to reach the band gap of 1.8 eV for In₁₋ₓAlₓAs_{1-y}Sb_{y}, where y is between 0.15 and 0.3 and x=(0.4748+1.0602y)/(1−0.1342y).

As also can be seen from the plot in FIG. 7B, an InP-based material system in accordance with the present invention offers considerable flexibility for optimizing the middle- and bottom-cell properties, with the desired band gaps being easily obtained by varying the composition of the InAlGaAs quaternary and/or InGaAsP. Thus, as can be seen from the plots in FIGS. 7A and 7B, the InGaAlAs Γ-valley crosses the optimum middle-cell band gap of between about 1.17 and 1.22 eV. This can achieved using b between 0.30 and 0.36.

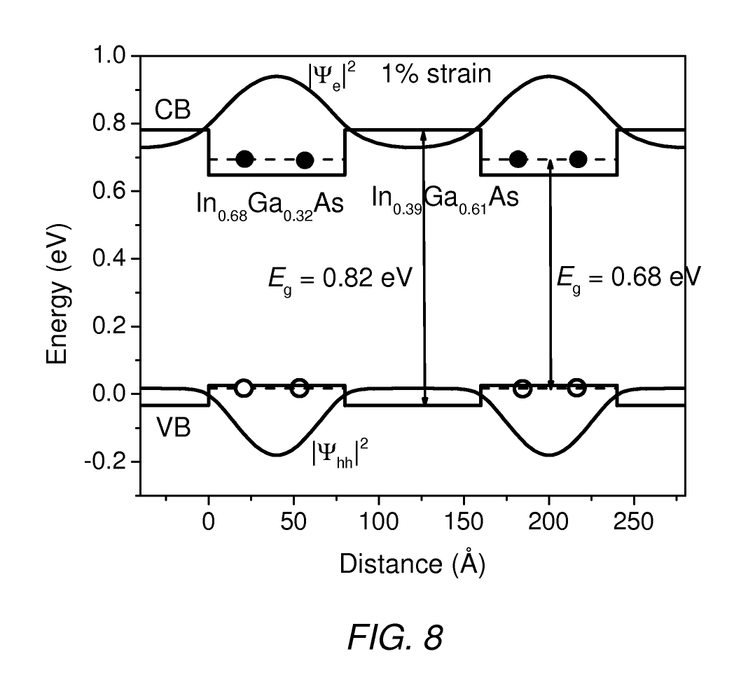

In addition, although the optimal 0.70 eV junction value lies slightly below the 0.74 eV band gap for lattice-matched InGaAs, this lower band gap can be accessed by placing multiple strain-balanced quantum wells (QWs) in the depletion region of the bottom cell. The plots in FIG. 8 illustrate this by showing the conduction band and valence band energy profiles for the lowest subbands, and corresponding electron and heavy-hole wavefunctions for a representative InGaAs/InGaAs QW structure with 0.86% compressive strain in the wells, the same amount of tensile strain in the barriers, and an energy gap of 0.70 eV. One reaches a lower energy gap in the QW than in the lattice-matched bulk In_{0.53}Ga_{0.47}As alloy because the strain compensation allows us to use an In_{0.68}Ga_{0.32}As alloy with larger In fraction and smaller band gap.

It is important to note that in the prior art, the need to grow materials on GaAs substrates has directed efforts towards the local maximum at 1.86 eV. Our methodology for identifying optimal band gap energies has highlighted the presence of the global maximum in efficiency with a top-cell at 1.74 eV followed by lower energy junctions with band gaps at (1.18 eV and 0.7 eV). Such band gaps are easily obtainable with InP lattice-matched alloys, but cannot be attained using presently available GaAs-based technology.

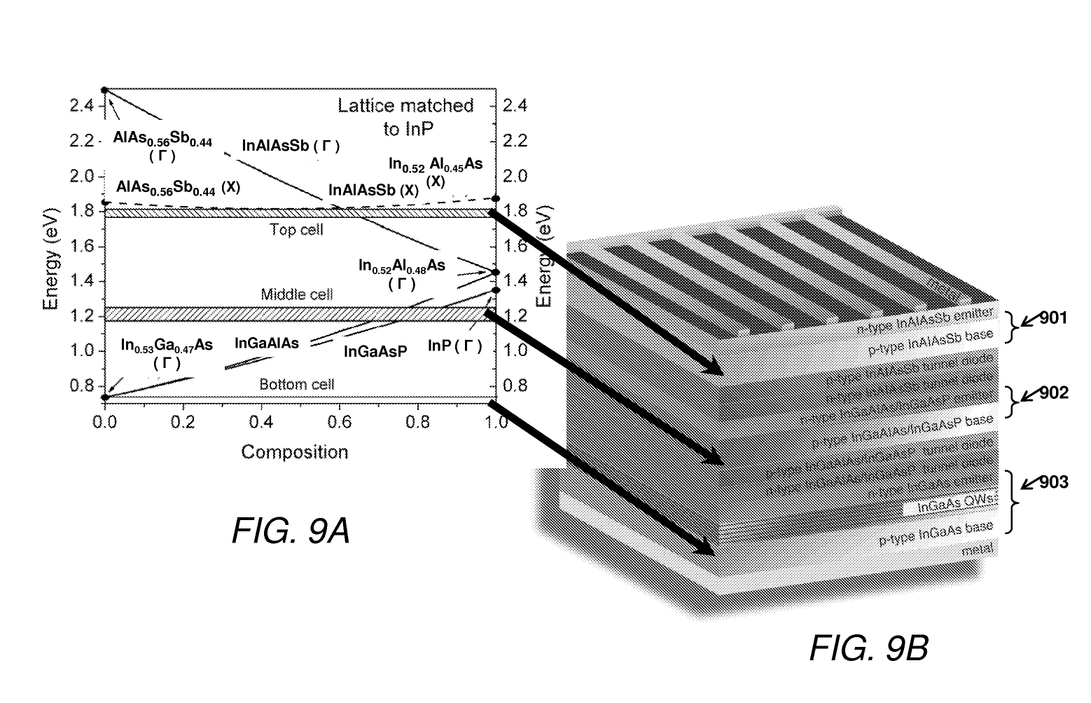

FIGS. 9A and 9B illustrate an exemplary embodiment of an InP lattice-matched MJ solar cell in accordance with the present invention and associate the band gaps and materials shown in FIG. 7B with the exemplary embodiment of the present invention shown in FIG. 1. FIG. 9A is a reproduction of FIG. 7B, showing the band gaps achievable with materials lattice matched to InP with the optimum band gaps determined from the present modeling, while FIG. 9B (which reproduces FIG. 1) gives a schematic diagram of one set of junctions with the requisite tunnel junctions to achieve the high efficiency MJ cells. Also indicated are the quantum well layers in the bottom junction used to tailor the bottom junction band gap.

Thus, as described above and as shown in FIGS. 9A and 9B, a top-cell band gap of about 1.78 to 1.8 eV can be achieved with the InAlAsSb materials used in top p-n junction 901 (also shown as p-n junction 101 in FIG. 1), a middle-cell band gap of about 1.18 to about 1.27 eV can be achieved with the InGaAlAs or InGaAsP materials used in middle p-n junction 902, and that a bottom-cell band gap of about 0.7 eV can be achieved with the InGaAs materials used in the bottom p-n junction and QWs 903.

### Advantages and New Features:

As described above, the inventors have found that In₁₋ₓAlₓAs_{1-y}Sb_{y} alloys can be used as the top cell material in a 3-junction MJ solar cell in accordance with the present invention, with this alloy being in the form In_{0.3}Al_{0.7}As_{0.83}Sb_{0.17} in a preferred embodiment. According to the inventors' calculations, an alloy having this composition can have a direct band gap of up to 1.8 eV and thus is quite suitable for optimizing the performance of a 3-junction MJ solar cell in accordance with the present invention. This particular In₁₋ₓAlₓAs_{1-y}Sb_{y} alloy concentration is determined so as to maximize the direct (Γ-valley) band gap while assuming that it is no larger than the indirect X-valley gap. If a semiconductor becomes indirect, it has negligible absorption below the Γ-valley transition and can exhibit a loss of voltage associated with carrier relaxation to the lower X-valley states.

### Alternatives:

Although particular embodiments, aspects, and features have been described and illustrated, one skilled in the art would readily appreciate that the invention described herein is not limited to only those embodiments, aspects, and features. Many variations on the structural parameters of the embodiment specified in FIG. 1 are possible while maintaining the new features and spirit of the invention. This particularly applies to the lattice-matched materials employed for the middle and bottom cells, whose band gaps may vary within a certain range without seriously compromising the overall power conversion efficiency.

For example, in some alternative embodiments, an MJ solar cell in accordance with the present invention can be formed using InGaAsP rather than InGaAlAs for the junctions of band gaps less than 1.4 eV.

Moreover, as noted above, an MJ solar cell in accordance with the present invention does not necessarily need to contain exactly three junctions to benefit from application of the invention. For example, in solar cells containing either two or four junctions it would still be advantageous to use InAlAsSb with the optimal alloy concentration for maximum energy gap as the absorber in the top cell.

A further alternative is to use strain-compensated quantum well or superlattice materials as the absorbers in the middle and/or bottom cell, or in the tunnel junctions connecting the cells.

All such combinations and embodiments and any others that may be made by ones skilled in the art are deemed to be within the scope and spirit of the present disclosure.

What is claimed is:

1. A method for designing a multi-junction solar cell comprising a top cell, a bottom cell, and at least one middle cell situated between the top cell and the bottom cell, an interface between each adjacent cell comprising a corresponding p-n junction, the method comprising the steps of:
(a) identifying a plurality of candidate materials for the multi-junction solar cell, each of the candidate materials having an associated lattice constant and an associated band gap;
(b) for each candidate material, determining its radiative efficiency η_{rad} as a function of a mismatch of its lattice constant with a lattice constant of a host substrate for the multijunction solar cell; and
(c) identifying an optimum combination of the candidate materials for each p-n junction, such that a combination of band gap and radiative efficiency η_{rad} of each identified combination of materials maximizes the overall solar conversion efficiency of the multi-junction solar cell.

2. The method according to claim 1, wherein the substrate is InP and at least one of the candidate materials is lattice-matched to InP.

3. The method according to claim 2, wherein the optimum combination of candidate materials for at least one p-n junction includes a material that is lattice-matched to InP.

4. A computer-implemented method for designing a multi-junction solar cell comprising a top cell, a bottom cell, and at least one middle cell situated between the top cell and the bottom cell, an interface between each adjacent cell comprising a corresponding p-n junction, the method comprising the following steps:
(a) receiving at a computer programmed with appropriate software, data of a plurality of candidate materials for the multi-junction solar cell, each of the candidate materials having an associated lattice constant and an associated band gap;
(b) using the computer, for each candidate material, determining its radiative efficiency η_{rad} as a function of a mismatch of its lattice constant with a lattice constant of a host substrate for the multijunction solar cell;
(c) using the computer, selecting one of the top, bottom, and middle cells and setting a band gap of the selected cell at a fixed value E_{g} and setting a radiative efficiency of the selected cell at a fixed value η_{rad};
(d) using the computer, identifying a first combination of candidate materials for the remaining cells of the solar cell;
(e) using the computer, calculating an overall radiative efficiency of a modeled multijunction solar cell having the fixed band gap E_{g}, the fixed radiative efficiency η_{rad}, and the first combination of candidate materials;
(f) repeating steps (c)-(e) for each combination of fixed band gap E_{g}, radiative efficiency η_{rad}, and candidate materials to obtain an optimum combination of candidate materials for a multijunction solar cell, wherein the optimum combination of materials maximizes an overall radiative efficiency η_{rad} of the solar cell.

5. The method according to claim 4, wherein the substrate is InP and at least one of the candidate materials is lattice-matched to InP.

6. The method according to claim 2, wherein the optimum combination of materials includes at least one material that is lattice-matched to InP.
